(19) United States
(12) Patent Application Publication
(10) Pub. No.: US 2010/0240225 A1
(43) Pub. Date: Sep. 23, 2010

(54) MICROWAVE PLASMA PROCESSING APPARATUS, MICROWAVE PLASMA PROCESSING METHOD, AND MICROWAVE-TRANSMISSIVE PLATE

(75) Inventors: Yoshihiro Sato, Hyogo-ken (JP); Takashi Kobayashi, Hyogo-ken (JP); Toshihiko Shiozawa, Hyogo-ken (JP); Daisuke Tamura, Hyogo-ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: Tokyo Electron Limited, Tokyo-To (JP)

(21) Appl. No.: 12/664,191

(22) PCT Filed: Jun. 10, 2008
(86) PCT No.: PCT/JP2008/060587

§ 371 Date: Jun. 4, 2010

(30) Foreign Application Priority Data
Jun. 14, 2007 (JP) 2007-157985

(51) Int. Cl. H01L 21/473; H01L 21/469; H05H 1/46

(52) U.S. Cl. 438/786; 118/723 AN; 257/E21.487; 257/E21.494

(57) ABSTRACT

Disclosed is a microwave plasma processing apparatus (100) that generates a plasma of a processing gas in a chamber (1) by microwaves radiated from microwave radiating holes (32) of a plane antenna (31) and transmitted through a microwave-transmissive plate (28), thereby to carry out plasma processing of a processing object with the plasma. The microwave-transmissive plate (28) has a microwave transmitting surface having a recessed/projected area (42) in an area corresponding to a peripheral region of the processing object, and having a flat area (43) in an area corresponding to a central region of the processing object (W).

### TECHNICAL FIELD

The present invention relates to a microwave plasma processing apparatus and method, and a microwave-transmissive plate for use in the apparatus and method, and more particularly to a technology for oxidizing a silicon nitride film by microwave plasma processing to form a silicon oxide film.

### BACKGROUND ART

Plasma processing is an essential technique in the manufacturing of semiconductor devices. Because of the demand for higher integration and higher speed of LSIs, design rules on semiconductor devices, constituting an LSI, are becoming increasingly finer these days. Further, there is a continuing trend toward larger-sized semiconductor wafers. There is, therefore, a demand for a plasma processing apparatus which can respond to the movement toward finer devices and larger-sized wafers.

Parallel plate type or inductively coupled type plasma processing apparatuses, which have heretofore been frequently used, can cause plasma damage to fine devices because of the high electron temperature used. In addition, due to a limited high-plasma density area, it is difficult with such apparatuses to plasma-process a large-sized semiconductor wafer uniformly at a high speed.

Attention has therefore been drawn to an RLSA (radial line slot antenna) microwave plasma processing apparatus capable of uniformly forming a high-density, low-electron temperature plasma (see, for example, International Publication WO2004/008519 Pamphlet).

An RLSA microwave plasma processing apparatus has, at the top of its processing chamber, a plane antenna (radial line slot antenna) having a large number of slots formed in a predetermined pattern. Microwaves guided from a microwave generation source are radiated form the slots of the plane antenna, and the microwaves are radiated into the chamber, which is kept in vacuum, via a microwave-transmissive plate of dielectric material provided under the plane antenna. A gas introduced into the chamber is turned into plasma by the microwave electric field, and a processing object, such as a semiconductor wafer, is processed with the plasma thus formed.

It is possible with such an RLSA microwave plasma processing apparatus to achieve a high plasma density in a wide area under the antenna and to perform uniform plasma processing in a short time. Furthermore, a low-electron temperature plasma, causing little damage to a device, can be formed.

Application of an RLSA microwave plasma processing apparatus to oxidation processing, utilizing the advantage of low-damage and uniform processing, has therefore been attracting attention. In the case of direct oxidation of a silicon substrate, such as the formation of a gate oxide film, relatively uniform oxidation processing has been achieved in a relatively high pressure environment in which radicals are dominant, because the Si—Si bond energy is about 2.3 eV.

On the other hand, an insulating film of a three-layer structure (ONO structure), consisting of an oxide film, a nitride film formed on the oxide film and an oxide film formed on the nitride film, is frequently used these days as an insulating film between a floating gate and a control gate in a nonvolatile memory device. An attempt has been made to carry out processing to form the final oxide film on a silicon nitride (SiN) film by means of an RLSA microwave plasma. In such oxidation processing, not only radicals but also ions having a higher energy are needed because the SiN bond energy is 3.5 eV.

When forming a plasma in which ions are present in a relatively large amount, however, control of the distribution of ions cannot be performed sufficiently, whereby an oxide film, formed on an SiN film, has a non-uniform convex thickness distribution.

### DISCLOSURE OF THE INVENTION

It is an object of the present invention to provide a microwave plasma processing apparatus which can control the distribution of ions in a plasma and can achieve highly uniform plasma processing with the ion-containing microwave plasma, and to provide a microwave-transmissive plate for use in the apparatus.

It is another object of the present invention to provide a microwave plasma processing apparatus and a microwave plasma processing method, which can form an oxide film having a high in-plane uniformity by carrying out oxidation processing of a silicon nitride film with a microwave plasma.

According to a first aspect of the present invention, there is provided a microwave plasma processing apparatus for forming a plasma of a processing gas by means of microwaves, and carrying out plasma processing of a processing object with the plasma, said apparatus comprising: a chamber for housing a processing object; a stage, disposed in the chamber, for placing the processing object thereon; a microwave generation source for generating microwaves; a waveguide mechanism for guiding the microwaves, generated by the microwave generation source, toward the chamber; a plane antenna made of a conductive material, having a plurality of microwave radiating holes for radiating the microwaves, guided by the waveguide mechanism, toward the chamber; a microwave-transmissive plate of dielectric material, constituting the ceiling of the chamber and permitting transmission of the microwaves that have passed through the microwave radiating holes of the plane antenna; and a processing gas supply mechanism for supplying a processing gas into the chamber, wherein a microwave transmitting surface of the microwave-transmissive plate has a recessed/projected area in an area corresponding to a peripheral region of the processing object, and a flat area in an area corresponding to a central region of the processing object.

In the first aspect, the flat area of the microwave-transmissive plate preferably accounts for 20 to 40% based on 100% of the recessed/projected area. The diameter of the flat area is preferably 50 to 80% of the diameter of the processing object. The recessed/projected area may be comprised of projected portions and recessed portions arranged alternately in concentric circles. Preferably in this case, the width of each projected portion is 4 to 23 mm, the width of each recessed portion is 3 to 22 mm, and the height of each projected portion is 1 to 10 mm. The plasma processing may be oxidation of a nitride film.

According to a second aspect of the present invention, there is provided a microwave plasma processing method comprising: placing a processing object, having a silicon nitride film in a surface, on a stage in a chamber; radiating microwaves from a plurality of microwave radiating holes formed in a plane antenna and allowing the microwaves to permeate a microwave-transmissive plate of a dielectric material, constituting the ceiling of the chamber, thereby introducing the microwaves into the chamber; supplying an oxygen-containing gas into the chamber; and turning the oxygen-containing gas into plasma by means of the microwaves introduced into the chamber, and carrying out oxidation of the silicon nitride film of the processing object with the plasma, wherein the microwaves are introduced into the chamber in such a manner as to make the distribution of ions in the plasma uniform over the surface of the processing object.

In the second aspect, as the microwave-transmissive plate may be used one whose microwave transmitting surface has a recessed/projected area in an area corresponding to a peripheral region of the processing object, and a flat area in an area corresponding to a central region of the processing object. In such microwave-transmissive plate, the flat area preferably accounts for 20 to 40% based on 100% of the recessed/projected area. The diameter of the flat area is preferably 50 to 80% of the diameter of the processing object. The recessed/projected area may preferably be comprised of projected portions and recessed portions arranged alternately in concentric circles. Preferably in this case, the width of each projected portion is 4 to 23 mm, the width of each recessed portion is 3 to 22 mm, and the height of each projected portion is 1 to 10 mm.

Further, in the second aspect, the plasma processing is preferably carried out under the conditions where the processing pressure in the chamber is 1.3 to 665 Pa, and the oxygen-containing gas contains oxygen gas in an amount of not less than 0.5% and less than 10%.

According to a third aspect of the present invention, there is provided a microwave-transmissive plate made of a dielectric material, constituting the ceiling of a chamber, which permits transmission of microwaves when placing a processing object on a stage in the chamber, and radiating microwaves from a plurality of microwave radiating holes formed in a plane antenna to introduce the microwaves into the chamber, wherein the microwave transmitting surface of the microwave-transmissive plate has a recessed/projected area in an area corresponding to a peripheral region of the processing object, and a flat area in an area corresponding to a central region of the processing object.

In the third aspect, the flat area preferably accounts for 20 to 40% based on 100% of the recessed/projected area. The diameter of the flat area is preferably 50 to 80% of the diameter of the processing object. The recessed/projected area may preferably be comprised of projected portions and recessed portions arranged alternately in concentric circles. Preferably in this case, the width of each projected portion is 4 to 23 mm, the width of each recessed portion is 3 to 22 mm, and the height of each projected portion is 1 to 10 mm.

According to the present invention, owing to the use of the microwave-transmissive plate whose microwave transmitting surface has a recessed/projected area in an area corresponding to a peripheral region of a processing object, and a flat area in an area corresponding to a central region of the processing object, the formation of a standing wave in the radial direction of the microwave-transmissive plate can be suppressed in the peripheral region. This can increase the ion density in plasma in the peripheral region, thereby attaining an ion distribution having a high in-plane uniformity. It is noted in this regard that when carrying out plasma processing which requires a relatively high energy, such as oxidation of silicon nitride, using an RLSA microwave plasma processing apparatus, it is necessary to use a plasma containing, in addition to radicals, a relatively large amount of ions. A convex ion distribution is known to be produced in such processing. According to the present invention, the use of the specific microwave-transmissive plate can provide a uniform ion distribution over the surface of a processing object by suppressing a standing wave in a peripheral region and thereby increasing the ion density in plasma in the peripheral region. This enables highly uniform plasma processing of the processing object.

### BRIEF DESCRIPTION OF THE DRAWINGS

FIG. 1 is a schematic cross-sectional diagram showing a microwave plasma processing apparatus according to an embodiment of the present invention.

FIG. 2 is a diagram showing the structure of the plane antenna member of the microwave plasma processing apparatus of FIG. 1.

FIG. 3A is a side view showing the structure of the microwave-transmissive plate of the microwave plasma processing apparatus of FIG. 1, and FIG. 3B is a bottom view showing the structure of the microwave-transmissive plate.

FIG. 4 is a diagram illustrating the relationship between the diameter of a wafer and the diameter of the flat area of the microwave-transmissive plate of the microwave plasma processing apparatus of FIG. 1.

FIG. 5 is a cross-sectional diagram illustrating an example of the application of the apparatus of the present invention.

FIG. 6A is a diagram illustrating the distribution of ion density in a comparative apparatus, and FIG. 6B is a diagram illustrating the distribution of ion density in the apparatus of the present invention.

### BEST MODE FOR CARRYING OUT THE INVENTION

Preferred embodiments of the present invention will now be described with reference to the drawings.

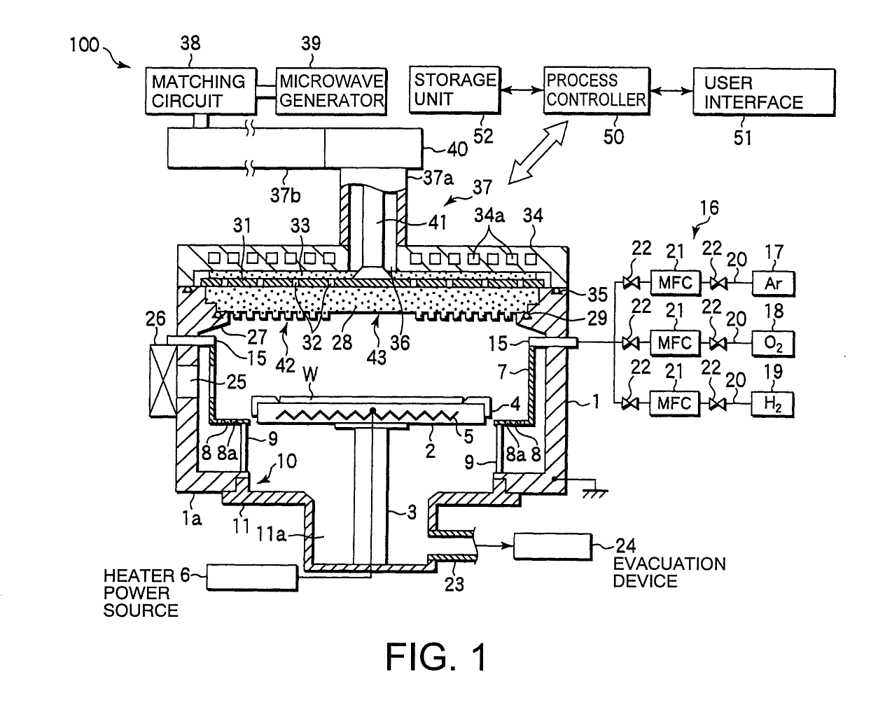

FIG. 1 is a cross-sectional diagram schematically showing a microwave plasma processing apparatus according to an embodiment of the present invention. The plasma processing apparatus is constructed as an RLSA microwave plasma processing apparatus capable of generating a high-density, low-electron temperature microwave plasma by introducing microwaves into a processing chamber by means of an RLSA (radial line slot antenna), which is a plane antenna having a plurality of slots. The apparatus is suited for use in plasma oxidation processing and, in this embodiment, is applied to oxidation of a nitride film.

The plasma processing apparatus 100 includes a generally-cylindrical airtight and grounded chamber 1. A circular opening 10 is formed generally centrally in the bottom wall la of the chamber 1. The bottom wall la is provided with a downwardly-projecting exhaust chamber 11 which communicates with the opening 10.

In the chamber 1 is provided a susceptor 2, made of a ceramic such as AlN, for horizontally supporting a semiconductor wafer (hereinafter referred to simply as “wafer”) W as a substrate to be processed. The susceptor 2 is supported by a cylindrical support member 3, made of a ceramic such as AlN, extending upwardly from the center of the bottom of the exhaust chamber 11. The susceptor 2, in its peripheral portion, is provided with a guide ring 4 for guiding the wafer W. A resistance heating-type heater 5 is embedded in the susceptor 2. The heater 5, when powered from a heater power source 6, heats the susceptor 2 and, by the heat, heats the wafer W as a processing object. The wafer processing temperature can be controlled e.g. in the range of room temperature to 800° C. A cylindrical liner 7 of high-purity quarts (with few impurities) is provided on the inner circumference of the chamber 1. The liner 7 can prevent contamination e.g. with a metal and create a clean environment. Further, an annular quartz baffle plate 8, having a large number of exhaust holes 8a for uniformly evacuating the chamber 1, is provided around the circumference of the susceptor 2. The baffle plate 8 is supported on support posts 9.

The susceptor 2 is provided with wafer support pins (not shown) for raising and lowering the wafer W while supporting it. The wafer support pins are each projectable and retractable with respect to the surface of the susceptor 2.

An annular gas introduction member 15 is provided in the side wall of the chamber 1, and gas radiating holes are formed uniformly in the gas introduction member 15. A gas supply system 16 is connected to the gas introduction member 15. It is also possible to use a gas introduction member having the shape of a shower head. The gas supply system 16 has, for example, an Ar gas supply source 17, an O₂ gas supply source 18 and an H₂ gas supply source 19. These gases each pass through a respective gas line 20 and reach the gas introduction member 15, and are uniformly introduced from the gas radiating holes of the gas introduction member 15 into the chamber 1. The gas lines 20 are each provided with a mass flow controller 21 and on-off valves 22 located upstream and downstream of the controller 21. Instead of Ar gas, other rare gases such as Kr, He, Ne and Xe may also be used.

An exhaust pipe 23 is connected to the side wall of the exhaust chamber 11, and to the exhaust pipe 23 is connected an exhaust device 24 including a high-speed vacuum pump. By the actuation of the exhaust device 24, the gas in the chamber 1 is uniformly discharged into the space 11a of the exhaust chamber 11, and discharged through the exhaust pipe 23 to the outside. The chamber 1 can thus be quickly depressurized into a predetermined vacuum level, e.g. 0.133 Pa.

The side wall of the chamber 1 is provided with a transfer port 25 for transferring the wafer W between the plasma processing apparatus 100 and an adjacent transfer chamber (not shown), and a gate valve 26 for opening and closing the transfer port 25.

The chamber 1 has a top opening, and a ring-shaped support 27 is provided along the periphery of the opening. A microwave-transmissive plate 28, which is made of a dielectric material, e.g. a ceramic such as quartz or Al₂O₃ and is transmissive to microwaves, is provided on the support 27. A seal member 29 for hermetic sealing is provided between the microwave-transmissive plate 28 and the support 27 so that the chamber 1 can be kept hermetic. The lower surface, i.e. the microwave transmitting surface, of the microwave-transmissive plate 28 has a recessed/projected area 42 in an area corresponding to a peripheral region of the wafer W (on the susceptor 2), and a flat area 43 in an area corresponding to a central region of the wafer W. The details of the microwave-transmissive plate 28 will be described later.

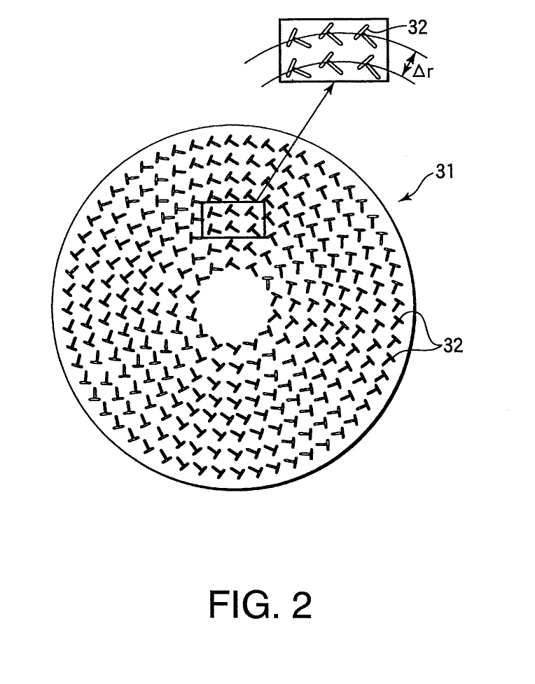

A disk-shaped plane antenna member 31 is provided over the microwave-transmissive plate 28 such that it faces the susceptor 2. The plane antenna member 31 is locked into the upper end of the side wall of the chamber 1. The plane antenna member 31 is a circular plate of conductive material and, when the wafer W is e.g. of 8-inch size, has a diameter of 300 to 400 mm and a thickness of 0.1 to a few mm (e.g. 1 mm). For example, the plane antenna member 31 is comprised of a copper or aluminum plate whose surface is plated with silver or gold, and has a large number of microwave radiating holes (slots) 32 penetrating the plane antenna member 31 and formed in a predetermined pattern. As shown in FIG. 2, each microwave radiating hole 32 is a slot-like hole, and adjacent two microwave radiating holes 32 are paired typically in a letter “T” arrangement. The pairs of microwave radiating holes 32 are arranged in concentric circles as a whole. The length of the microwave radiating holes 32 and the spacing in their arrangement are determined depending on the wavelength (λg) of microwaves. For example, the microwave radiating holes 32 are arranged with a spacing of λg/4 to λg. In FIG. 2, the spacing between adjacent concentric lines of microwave radiating holes 32 is denoted by Δr.

The microwave radiating holes 32 may have other shapes, such as a circular shape and an arch shape. The arrangement of the microwave radiating holes 32 is not limited to the concentric arrangement: the microwave radiating holes 32 may be arranged e.g. in a spiral or radial arrangement.

A retardation member 33 e.g. made of quartz or a resin such as polytetrafluoroethylene or polyimide, having a higher dielectric constant than vacuum, is provided on the upper surface of the plane antenna member 31. The retardation member 33 is employed in consideration of the fact that the wavelength of microwaves becomes longer in vacuum. The retardation member 33 functions to shorten the wavelength of microwaves, thereby adjusting plasma. The plane antenna member 31 and the microwave-transmissive plate 28, and the retardation member 33 and the plane antenna member 31 may be in contact with or spaced apart from each other.

A conductive cover 34, made of a metal material such as aluminum, stainless steel or copper, is provided on the upper surface of the chamber 1 such that it covers the plane antenna member 31 and the retardation member 33. The contact area between the upper surface of the chamber 1 and the conductive cover 34 is sealed with a seal member 35. A cooling water flow passage 34a is formed in the interior of the conductive cover 34. The conductive cover 34, the retardation member 33, the plane antenna member 31 and the microwave-transmissive plate 28 are cooled by passing cooling water through the cooling water flow passage 34a. The conductive cover 34 is grounded.

An opening 36 is formed in the center of the upper wall of the conductive cover 34, and a waveguide 37 is connected to the opening 36. The other end of the waveguide 37 is connected via a matching circuit 38 to a microwave generator 39. Thus, microwaves e.g. having a frequency of 2.45 GHz, generated in the microwave generator 39, are propagated through the waveguide 37 to the plane antenna member 31. Other microwave frequencies, such as 8.35 GHz, 1.98 GHz, etc., can also be used.

The waveguide 37 is comprised of a coaxial waveguide 37a having a circular cross-section and extending upward from the opening 36 of the conductive cover 34, and a horizontally-extending rectangular waveguide 37b connected via a mode converter 40 to the upper end of the coaxial waveguide 37a. The mode converter 40 between the rectangular waveguide 37b and the coaxial waveguide 37a functions to convert microwaves, propagating in TE mode through the rectangular waveguide 37b, into TEM mode. An inner conductor 41 extends centrally in the coaxial waveguide 37a. The lower end of the inner conductor 41 is connected and secured to the center of the plane antenna member 31. Thus, microwaves are propagated through the inner conductor 41 of the coaxial waveguide 37a to the plane antenna member 31 uniformly and efficiently.

The components of the plasma processing apparatus 100 are each connected to and controlled by a process controller 50 provided with a microprocessor (computer). To the process controller 50 is connected a user interface 51 which includes a keyboard for an operator to perform a command input operation, etc. in order to manage the plasma processing apparatus 100, a display which visualizes and displays the operating situation of the plasma processing apparatus 100, etc. To the process controller 50 is also connected a storage unit 52 in which are stored a control program for executing, under control of the process controller 50, various process steps to be carried out in the plasma processing apparatus 100, and a program, or a recipe, for causing the respective components of the plasma processing apparatus 100 to execute their processing in accordance with processing conditions. The recipe is stored in a storage medium in the storage unit 52. The storage medium may be a hard disk or a semiconductor memory, or a portable medium such as CD-ROM, DVD, flash memory, etc. It is also possible to transmit the recipe from another device e.g. via a dedicated line as needed.

A desired processing in the plasma processing apparatus 100 is carried out under the control of the process controller 50 by calling up an arbitrary recipe from the storage unit 52 and causing the process controller 50 to execute the processing recipe, e.g. through the operation of the user interface 51 performed as necessary.

The microwave-transmissive plate 28 will now be described in detail.

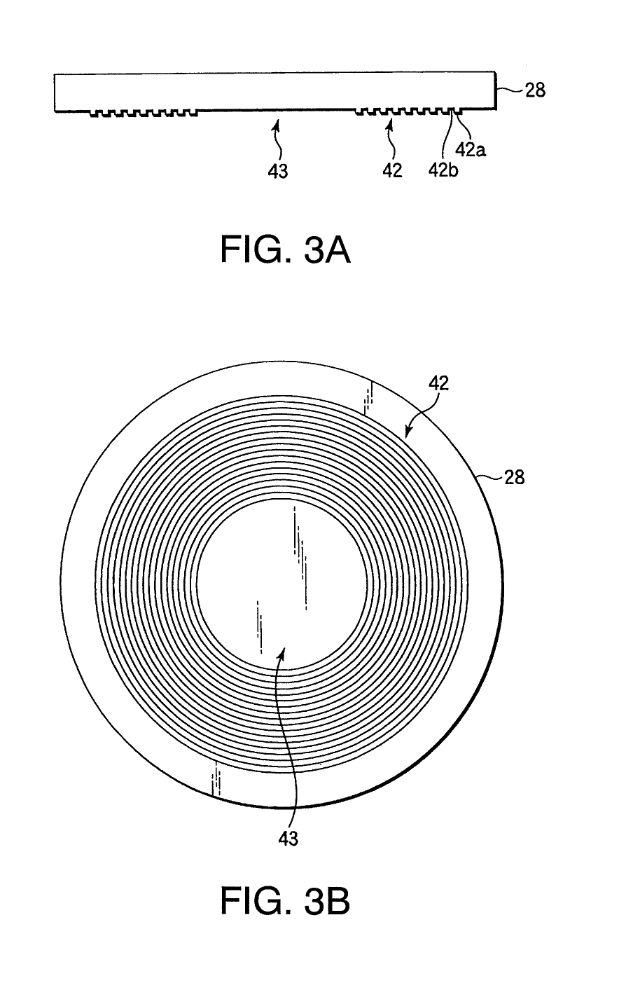

As shown in FIG. 3A, the microwave transmitting surface of the microwave-transmissive plate 28 has, in an area including the region corresponding to a peripheral region of the wafer W, a recessed/projected area 42 in which projected portions 42a and recessed portions 42b are formed alternately and has, in the region corresponding to a central region of the wafer W, a flat area 43. The projected portions 42a and the recessed portions 42b of the recessed/projected area 42 are arranged in concentric circles as shown in FIG. 3B. The recessed/projected area 42 acts to suppress the formation of a standing wave in the radial direction of the microwave-transmissive plate 28 and increase the density of plasma in the peripheral region, thereby makes the distribution of the plasma uniform. Thus, the plasma density (ion density) increases in the region including the recessed/projected area 42 and corresponding to the peripheral region of the wafer W.

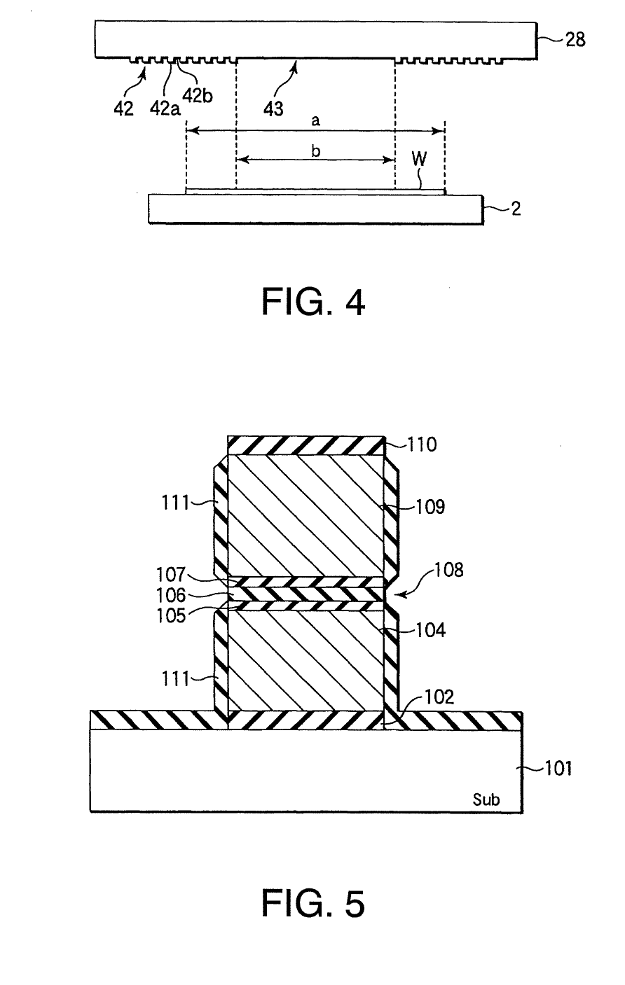

The recessed/projected area 42 may be formed at least in an area from a portion, corresponding to a peripheral portion of the wafer W at which the ion density begins to decrease from that in the central region of the wafer W, to the portion corresponding to the edge of the wafer W. Thus, the tendency of ion distribution to become a convex distribution can be eliminated by raising the ion density in the peripheral region. On the other hand, the flat area 43 of the microwave-transmissive plate 28 corresponds to the region of the wafer W for which increase of the ion density is not necessary. From such viewpoint, it is preferred that the ratio of the diameter “b” of the flat area 43 to the diameter “a” of the wafer W (b/a) be made 50 to 80%, as shown in FIG. 4. That is, the width of the peripheral recessed/projected area 42 is preferably made at least 20 to 50% of the radius of the wafer W. This can effectively make the distribution of ions uniform. From the viewpoint of efficiently eliminating a standing wave, the width of each projected portion 42a is preferably 4 to 23 mm, the width of each recessed portion 42b is preferably 3 to 22 mm, and the height of each projected portion 42a is preferably 1 to 10 mm. More preferably, the width of each projected portion 42a is 6 to 14 mm, the width of each recessed portion 42b is 5 to 13 mm, and the height of each projected portion 42a is 3 to 8 mm. The recessed/projected area 42 of the microwave-transmissive plate 28 is preferably formed to the end of the microwave transmitting surface, excluding a margin for mounting of the microwave-transmissive plate 28. Further, the flat area 43 preferably accounts for 20 to 40% based on 100% of the recessed/projected area 42.

The microwave plasma processing apparatus 100 is suited for plasma oxidation processing, especially for oxidation of a silicon nitride (SiN) film, for which an ion-assisted high-energy plasma processing is required. A preferable example of such oxidation of a silicon oxide film is oxidation of a nitride film between a floating gate and a control gate in a nonvolatile memory device as shown in FIG. 5. In particular, the memory device comprises: an Si substrate 101; a tunnel oxide film 102 formed on the main Si surface; a floating gate 104 of polysilicon formed on the tunnel oxide film 102; an insulating film 108, e.g. having an ONO structure of an oxide film 105, a nitride film 106 and an oxide film 107, formed on the floating gate 104; a control gate 109 of polysilicon or of a laminate film of polysilicon and, for example, tungsten silicide, formed on the insulating film 108; an insulating layer 110 of SiN, SiO₂ or the like, formed on the control gate 109; and a side wall oxide film 111 formed by oxidation of the floating gate 104 and the control gate 109. In the nonvolatile memory device, the oxide film 105 is formed e.g. by thermal CVD, plasma CVD or plasma oxidation, and the nitride film 106 is formed e.g. by thermal CVD or plasma CVD. When forming the oxide film 107 on the nitride film 106, the microwave plasma processing apparatus 100 of this embodiment can be advantageously used.

Plasma oxidation processing of a silicon nitride (SiN) film to form such an oxide film can be carried out in the following manner: First, the gate valve 26 is opened, and a wafer W, having a surface nitride film to be processed, is carried from the transfer port 25 into the chamber 1 and placed on the susceptor 2.

Ar gas and O₂ gas are supplied from the Ar gas supply source 17 and the O₂ gas supply source 18 of the gas supply system 16 and introduced through the gas introduction member 15 into the chamber 1 respectively at a predetermined flow rate; and a predetermined processing pressure is maintained. The SiN bond energy, which is 3.5 eV, is higher than the Si—Si bond energy which is 2.3 eV. Therefore, oxidation of a silicon nitride film insufficiently progresses in a relatively high pressure environment in which radicals are dominant, such as in direct oxidation processing of an Si substrate. Accordingly, in order to utilize the energy of ions, the oxidation processing is preferably carried out under low-pressure, low-oxygen concentration conditions using a relatively low processing pressure and a low concentration of O₂ gas.

More specifically, the processing pressure in the chamber is preferably 1.3 to 665 Pa, more preferably 1.3 to 266.6 Pa, most preferably 1.3 to 133.3 Pa. The content of oxygen in the processing gas (flow rate ratio, i.e. volume ratio) is preferably not less than 0.5% and less than 20%, more preferably 0.5 to 5%, most preferably 0.5 to 2.5%. The flow rate of Ar gas may be selected from the range of 0 to 5000 mL/min, preferably from the range of 0 to 1500 mL/min, and the flow rate of O₂ gas may be selected from the range of 1 to 500 mL/min, preferably from the range of 1 to 50 mL/min, such that the proportion of O₂ gas in the total amount of the processing gas satisfies the above value.

In addition to Ar gas and O₂ gas from the Ar gas supply source 17 and the O₂ gas supply source 18, a predetermined amount of H₂ gas may also be supplied from the H₂ gas supply source 19. The supply of H₂ gas can increase the oxidation rate in plasma oxidation processing. This is because OH radicals are generated by the supply of H₂ gas, and the OH radicals contribute to increasing the oxidation rate. In this case, the amount of H₂ is preferably 0.1 to 10% of the total amount of the processing gas, more preferably 0.1 to 5%, and most preferably 0.1 to 2%. The flow rate of H₂ gas is preferably 1 to 650 mL/min (sccm), more preferably 0.5 to 20 mL/min (sccm).

The processing temperature may be in the range of 200 to 800° C., preferably in the range of 400 to 600° C.

Next, microwaves from the microwave generator 39 are introduced via the matching circuit 38 into the waveguide 37. The microwaves pass through the rectangular waveguide 37b, the mode converter 40 and the coaxial waveguide 37a, and are supplied to the plane antenna 31. The microwaves propagate in TE mode in the rectangular waveguide 37b, the TE mode of the microwaves are converted into TEM mode by the mode converter 40 and the TEM mode microwaves are propagated in the coaxial waveguide 37a toward the plane antenna 31. The microwaves are then radiated from the plane antenna 31 through the microwave-transmissive plate 28 into the space above the wafer W in the chamber 1. The power of the microwave generator 39 is preferably 0.5 to 5 kW.

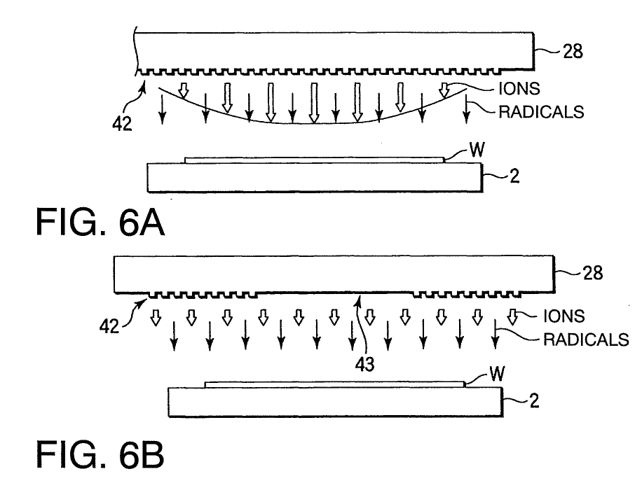

When a conventional flat microwave-transmissive plate is used to form the above-described high-energy plasma containing ions by means of such microwaves, the ion density tends to be high in the central region of the wafer W and low in the peripheral region. On the other hand, it is known that for a plasma in which radicals are dominant, the use of a microwave-transmissive plate, having a recessed/projected surface in which projected portions and recessed portions are arranged in concentric circles, can prevent the formation of a standing wave in the radial direction of the microwave-transmissive plate, thereby forming a uniform high-density plasma. An attempt has therefore been made to provide a recessed/projected area 42 substantially in the entire area of the microwave transmitting surface of a microwave-transmissive plate 28, as shown in FIG. 6A. When a high-energy plasma containing ions is formed by using a microwave plasma apparatus which employs such a microwave-transmissive plate, the distribution of radical density in the plasma is uniform, whereas the ion density is likely to be high in the central region and low in the peripheral region, as shown in FIG. 6A. It is therefore difficult to carry out uniform oxidation processing.

In contrast, by using the microwave-transmissive plate 28 of this embodiment, in which the microwave transmitting surface has the recessed/projected area 42 in an area corresponding to the peripheral region of the wafer W and the flat area 43 in an area corresponding to the central region of the wafer W, the ion density in plasma can be increased only in an region corresponding to that peripheral region of the wafer W for which increase of the ion density is intended, as shown in FIG. 6B. This makes it possible to produce an uniform ion distribution over the entire surface of the wafer W and carry out uniform oxidation of a nitride film, thus enhancing the uniformity of the oxide film formed.

A description will now be made of oxidation processing actually carried out with the use of the microwave plasma processing apparatus of the present invention.

First, using the apparatus of FIG. 1, plasma oxidation of an SiN film, which had been formed by CVD, was carried out under the following conditions to oxidize the surface of the SiN film, thereby forming an oxide film.
Processing pressure: 80 Pa
Gas flow rate: Ar/O₂/H₂=500/5/1.5 (mL/min (sccm))
Processing time: 180 sec
Microwave power: 4000 W
Temperature: 600° C.

For comparison, plasma oxidation of an SiN film to form an oxide film was carried out under the same conditions, but using an apparatus (comparative apparatus) which employs a microwave-transmissive plate in which the recessed/projected area is provided substantially in the entire area of the microwave transmitting surface.

The following results were obtained:

### <Apparatus of the Invention>

Average thickness of oxide film: 8.72 nm
Range of change in film thickness: 1.34 nm
Variation in film thickness (range/2× average): 7.7%
<Comparative Apparatus>
Average thickness of oxide film: 9.26 nm
Range of change in film thickness: 3.88 nm
Variation in film thickness (range/2× average): 21.5%

Next, using the apparatus of the present invention or the apparatus (comparative apparatus) which employs a microwave-transmissive plate in which the recessed/projected area is provided substantially in the entire area of the microwave transmitting surface, plasma oxidation of the surface of a bare Si wafer to form an oxide film was carried out under the same conditions. The results are as follows:

### <Apparatus of the Invention>

Average thickness of oxide film: 11.26 nm
Range of change in film thickness: 0.85 nm
Variation in film thickness (range/2× average): 3.8%

### <Comparative Apparatus>

Average thickness of oxide film: 12.48 nm
Range of change in film thickness: 1.12 nm
Variation in film thickness (range/2× average): 4.5%

As will be appreciated from the above results, in the case of oxidation of the surface of a bare Si wafer to form an oxide film, a sufficient uniformity of the thickness of the oxide film can be obtained also by the use of the comparative apparatus. However, in the case of the formation of an oxide film in the surface of an SiN film, the oxide film formed by the use of the comparative apparatus has a considerably large variation in the film thickness. On the other hand, the use of the apparatus of the present invention can form an oxide film with an significantly enhanced thickness uniformity.

As a result of further experimental studies using the apparatus of the present invention, the following conditions have been found to be optimal for oxidation of an SiN film:
Processing pressure: 80 Pa
Gas flow rate: Ar/O₂/H₂=500/5/0.7 (mL/min (sccm))
Processing time: 180 sec
Microwave power: 3600 W
Temperature: 600° C.

The oxide film formed under the optimal conditions was as follows:
Average thickness of oxide film: 7.16 nm
Range of change in film thickness: 0.94 nm
Variation in film thickness (range/2× average): 6.6%

Plasma oxidation of a bare Si wafer was carried out under the same conditions. The results are as follows:
Average thickness of oxide film: 9.37 nm
Range of change in film thickness: 0.72 nm
Variation in film thickness (range/2× average): 3.9%

The present invention is not limited to the embodiments described above, but various modifications may be made thereto. For example, while the present invention has been described with reference to its application to oxidation of a silicon nitride (SiN) film for the formation of an ONO insulating film in a nonvolatile memory device, the present invention is not limited to application in such a semiconductor device. Further, while the apparatus of the present invention has been described with reference to its application to oxidation of a nitride film, the present invention is also applicable to oxidation of other types of films insofar as the oxidation processing is carried out by means of an RLSA microwave plasma processing apparatus.

### INDUSTRIAL APPLICABILITY

The present invention can be advantageously used for oxidation of a silicon nitride (SiN) film in the manufacturing of various semiconductor devices.

1. A microwave plasma processing apparatus for forming a plasma of a processing gas by means of microwaves, and carrying out plasma processing of a processing object with the plasma, said apparatus comprising:
a chamber for housing a processing object;
a stage, disposed in the chamber, for placing the processing object thereon;
a microwave generation source for generating microwaves;
a waveguide mechanism for guiding the microwaves, generated by the microwave generation source, toward the chamber;
a plane antenna made of a conductive material, having a plurality of microwave radiating holes for radiating the microwaves, guided by the waveguide mechanism, toward the chamber;
a microwave-transmissive plate made of a dielectric material, constituting the ceiling of the chamber and permitting transmission of the microwaves that have passed through the microwave radiating holes of the plane antenna; and
a processing gas supply mechanism for supplying a processing gas into the chamber,
wherein a microwave transmitting surface of the microwave-transmissive plate has a recessed/projected area in an area corresponding to a peripheral region of the processing object, and a flat area in an area corresponding to a central region of the processing object.

2. The microwave plasma processing apparatus according to claim 1, wherein the flat area of the microwave-transmissive plate accounts for 20 to 40% based on 100% of the recessed/projected area.

3. The microwave plasma processing apparatus according to claim 1, wherein the diameter of the flat area is 50 to 80% of the diameter of the processing object.

4. The microwave plasma processing apparatus according to claim 1, wherein the recessed/projected area is comprised of projected portions and recessed portions arranged alternately in concentric circles.

5. The microwave plasma processing apparatus according to claim 4, wherein the width of each projected portion is 4 to 23 mm, the width of each recessed portion is 3 to 22 mm, and the height of each projected portion is 1 to 10 mm.

6. The microwave plasma processing apparatus according to claim 1, wherein the plasma processing is oxidation of a nitride film.

7. A microwave plasma processing method comprising:
placing a processing object, having a silicon nitride film in a surface, on a stage in a chamber;
radiating microwaves from a plurality of microwave radiating holes formed in a plane antenna and allowing the microwaves to transmit through a microwave-transmissive plate of a dielectric material, constituting the ceiling of the chamber, thereby introducing the microwaves into the chamber;
supplying an oxygen-containing gas into the chamber; and
turning the oxygen-containing gas into plasma by means of the microwaves introduced into the chamber, and carrying out oxidation of the silicon nitride film of the processing object with the plasma, wherein the microwaves are introduced into the chamber in such a manner as to make the distribution of ions in the plasma uniform over the surface of the processing object.

8. The microwave plasma processing method according to claim 7, wherein as the microwave-transmissive plate is used one whose microwave transmitting surface has a recessed/projected area in an area corresponding to a peripheral region of the processing object, and a flat area in an area corresponding to a central region of the processing object.

9. The microwave plasma processing method according to claim 8, wherein the flat area of the microwave-transmissive plate accounts for 20 to 40% based on 100% of the recessed/projected area.

10. The microwave plasma processing method according to claim 8, wherein the diameter of the flat area is 50 to 80% of the diameter of the processing object.

11. The microwave plasma processing method according to claim 8, wherein the recessed/projected area is comprised of projected portions and recessed portions arranged alternately in concentric circles.

12. The microwave plasma processing method according to claim 11, wherein the width of each projected portion is 4 to 23 mm, the width of each recessed portion is 3 to 22 mm, and the height of each projected portion is 1 to 10 mm.

13. The microwave plasma processing method according to claim 7, wherein the plasma processing is carried out under conditions where the processing pressure in the chamber is 1.3 to 665 Pa, and the oxygen-containing gas contains oxygen gas in an amount of not less than 0.5% and less than 10%.

14. A microwave-transmissive plate made of a dielectric material, constituting the ceiling of a chamber, which permits transmission of microwaves when placing a processing object on a stage in the chamber, and radiating microwaves from a plurality of microwave radiating holes formed in a plane antenna to introduce the microwaves into the chamber, wherein a microwave transmitting surface of the microwave-transmissive plate has a recessed/projected area in an area corresponding to a peripheral region of the processing object, and a flat area in an area corresponding to a central region of the processing object.

15. The microwave-transmissive plate according to claim 14, wherein the flat area accounts for 20 to 40% based on 100% of the recessed/projected area.

16. The microwave-transmissive plate according to claim 14, wherein the diameter of the flat area is 50 to 80% of the diameter of the processing object.

17. The microwave-transmissive plate according to claim 14, wherein the recessed/projected area is comprised of projected portions and recessed portions arranged alternately in concentric circles.

18. The microwave-transmissive plate according to claim 17, wherein the width of each projected portion is 4 to 23 mm, the width of each recessed portion is 3 to 22 mm, and the height of each projected portion is 1 to 10 mm.
